(19) United States
(12) Patent Application Publication
(10) Pub. No.: US 2025/0226187 A1
(43) Pub. Date: Jul. 10, 2025

(54) SUBSTRATE PROCESSING APPARATUS FOR ETCHING A SUBSTRATE BY USING PLASMA

(71) Applicant: SAMSUNG ELECTRONICS CO., LTD., SUWON-SI (KR)

(72) Inventors: Heewon MIN, Suwon-si (KR); Jihwan KIM, Suwon-si (KR); Kyungsun KIM, Suwon-si (KR); Namkyun KIM, Suwon-si (KR); Mingil KIM, Suwon-si (KR); Donghyeon NA, Suwon-si (KR); Kuihyun YOON, Suwon-si (KR)

(21) Appl. No.: 19/000,909

(22) Filed: Dec. 24, 2024

(30) Foreign Application Priority Data
Jan. 4, 2024 (KR) 10-2024-0001732

(51) Int. Cl. H01J 37/32

(52) U.S. Cl. CPC H01J 37/32577; H01J 37/32128; H01J 37/3244; H01J 37/32541; H01J 37/32715; H01J 2237/3341

(57) ABSTRACT

A substrate processing apparatus includes: a ceramic puck supporting a substrate; and a pedestal arranged underneath the ceramic puck and to which a source radio frequency (RF) for generating plasma is applied, wherein a bias electrode, to which a non-sinusoidal generator voltage is applied, is arranged inside the ceramic puck.

### CROSS-REFERENCE TO RELATED APPLICATION

This application claims priority under 35 U.S.C. § 119 to Korean Patent Application No. 10-2024-0001732, filed on Jan. 4, 2024, in the Korean Intellectual Property Office, the disclosure of which is incorporated by reference herein in its entirety.

### TECHNICAL FIELD

The present inventive concept relates to a substrate processing apparatus, and more particularly, to a substrate processing apparatus for etching a substrate by using plasma.

### DISCUSSION OF THE RELATED ART

Plasma may be used in processes of processing substrates. For example, plasma may be used in etching, deposition, or dry cleaning processes that are performed on substrates. Plasma may be generated by excessively high temperatures, strong electric fields, or radio frequency (RF) electromagnetic fields. Plasma refers to an ionized gaseous state including ions, electrons, radicals, and the like. Dry cleaning, ashing, or etching processes that use plasma may be performed when ions or radical particles that are contained in plasma collide with substrates.

In the case of dry etching processes that uses plasma, generated reactive ions may be accelerated in directions of substrates by electric fields, and thus, films that are formed on the substrates or the substrates may be etched. Therefore, methods and devices for controlling the reactive ions accelerated in the directions of the substrates during the dry etching processes is currently under development.

### SUMMARY

According to an embodiment of the present inventive concept, a substrate processing apparatus includes: a ceramic puck supporting a substrate; and a pedestal arranged underneath the ceramic puck and to which a source radio frequency (RF) for generating plasma is applied, wherein a bias electrode, to which a non-sinusoidal generator voltage is applied, is arranged inside the ceramic puck.

According to an embodiment of the present inventive concept, a substrate processing apparatus includes: a housing; a shower head unit installed inside the housing and supplying a process gas for processing a substrate in the housing; a substrate support unit installed under the shower head unit inside the housing, wherein the substrate is disposed on the substrate support unit; and a plasma generation unit configured to generate plasma by using the process gas to process the substrate, wherein the substrate support unit includes: a chucking unit supporting the substrate by using an electrostatic force; and a base plate supporting the chucking unit, wherein the chucking unit includes: a ceramic puck supporting the substrate and having arranged therein a bias electrode, to which a non-sinusoidal voltage is applied; and a pedestal arranged underneath the ceramic puck and to which a source RF for generating plasma is applied, wherein the bias electrode has a disk shape and includes a reinforcement portion having a locally reinforced thickness, and a terminal portion of a bias rod is connected to a lower surface of the bias electrode through the reinforcement portion.

According to an embodiment of the present inventive concept, a substrate processing apparatus includes: a ceramic puck supporting a substrate; and a pedestal arranged underneath the ceramic puck and to which a source radio frequency (RF) for generating plasma is applied, wherein a bias electrode having a disk shape, in which a thickness of a center portion is different from a thickness of an edge portion, is arranged inside the ceramic puck.

### BRIEF DESCRIPTION OF THE DRAWINGS

The above and other aspects of the present inventive concept will become more apparent by describing in detail embodiments thereof, with reference to the accompanying drawings, in which:

FIG. 1 is a cross-sectional view schematically illustrating a structure of a substrate processing apparatus according to an embodiment of the present inventive concept;

FIG. 2 is an enlarged cross-sectional view illustrating a chucking unit according to an embodiment of the present inventive concept;

FIG. 3 is a cross-sectional view of a ceramic puck according to an embodiment of the present inventive concept;

FIG. 4 is a cross-sectional view of a ceramic puck according to an embodiment of the present inventive concept;

FIGS. 5A and 5B are cross-sectional views of a ceramic puck including a bias electrode having a thick center portion, according to an embodiment of the present inventive concept;

FIGS. 6A and 6B are cross-sectional views of a ceramic puck including a bias electrode having a thick edge portion, according to an embodiment of the present inventive concept;

FIG. 7 is an enlarged cross-sectional view illustrating a chucking unit according to an embodiment of the present inventive concept;

FIG. 8 is a perspective view schematically illustrating a structure of a terminal portion of FIG. 7; and

FIG. 9 is an enlarged cross-sectional view illustrating a chucking unit according to an embodiment of the present inventive concept.

### DETAILED DESCRIPTION OF THE EMBODIMENTS

Hereinafter, embodiments of the present inventive concept will be described in detail with reference to the accompanying drawings. The same reference numerals are used for the same components in the drawings and specification, and repeated descriptions thereof are omitted or briefly discussed.

It is noted that, as used herein, the terms “substantially,” “about,” and other similar terms, are used as terms of approximation, not as terms of degree, and thus are utilized to account for inherent deviations in measured, calculated, and/or provided values that would be recognized by one of ordinary skill in the art.

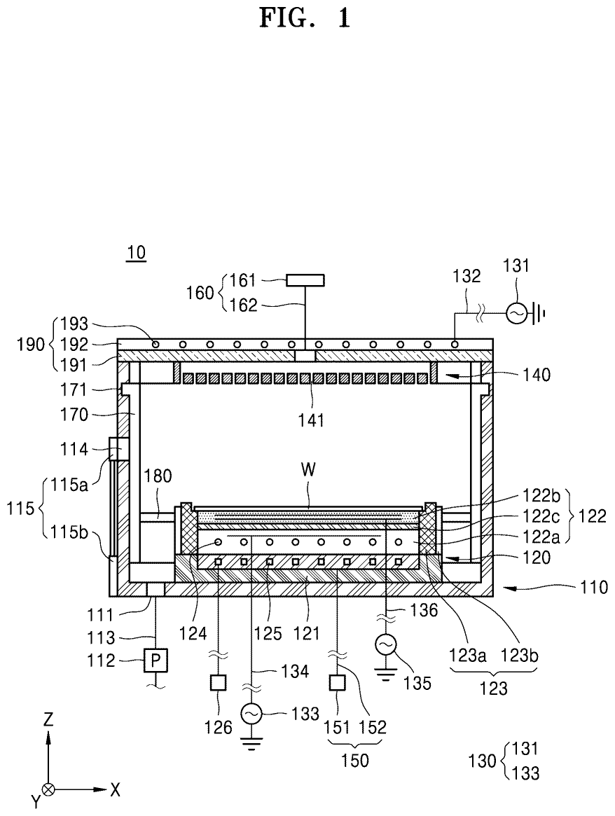

FIG. 1 is a cross-sectional view schematically illustrating a structure of a substrate processing apparatus 10 according to an embodiment of the present inventive concept.

Referring to FIG. 1, the substrate processing apparatus 10 may include a housing 110, a substrate support unit 120, a plasma generation unit 130, a shower head unit 140, a first gas supply unit 150, a second gas supply unit 160, a wall liner unit 170, a baffle unit 180, and an upper module 190.

The substrate processing apparatus 10 may be an apparatus that processes a substrate W by using an etching process (e.g., a dry etching process) in a vacuum environment. The substrate processing apparatus 10 may process the substrate W by using, for example, a plasma process.

The housing 110 may provide a space in which the plasma process is performed. The housing 110 may have an exhaust hole 111 in a lower portion thereof.

The exhaust hole 111 may be connected to an exhaust line 113 on which a pump 112 is mounted. The exhaust hole 111 may provide a passage for discharging reaction by-products, which are generated during the plasma process, and a gas remaining inside the housing 110 to the outside of the housing 110 through the exhaust line 113. Here, the inner space of the housing 110 may be decompressed to certain pressure. For example, a plurality of exhaust holes 111 may be formed in the lower portion of the housing 110.

The housing 110 may have an opening 114 formed in a sidewall thereof. The opening 114 may function as a passage through which the substrate W enters and exits the housing 110. The opening 114 may be configured to be opened and closed by a door assembly 115.

The door assembly 115 may include an outer door 115a and a door driver 115b. The outer door 115a may be provided on the outer wall of the housing 110. The outer door 115a may be moved in a vertical direction (in a Z direction) by the door driver 115b. The door driver 115b may operate by using, for example, a motor, a hydraulic cylinder, a pneumatic cylinder, or the like.

The substrate support unit 120 may be located in an inner lower region of the housing 110 and may support the substrate W. The substrate support unit 120 may fix the substrate W by using an electrostatic force or may support the substrate W by a mechanical clamping method. Hereinafter, the method by which the substrate support unit 120 fixes the substrate W by using the electrostatic force is described as an example.

The substrate support unit 120 may be implemented as an electrostatic chuck (ESC) including a base plate 121 and a chucking unit 122.

The base plate 121 may support the chucking unit 122. The base plate 121 may be, for example, provided as an aluminum (Al) base plate made of an aluminum component. According to embodiments of the present inventive concept, a cooling unit 125, which is described below, may be arranged on the base plate 121.

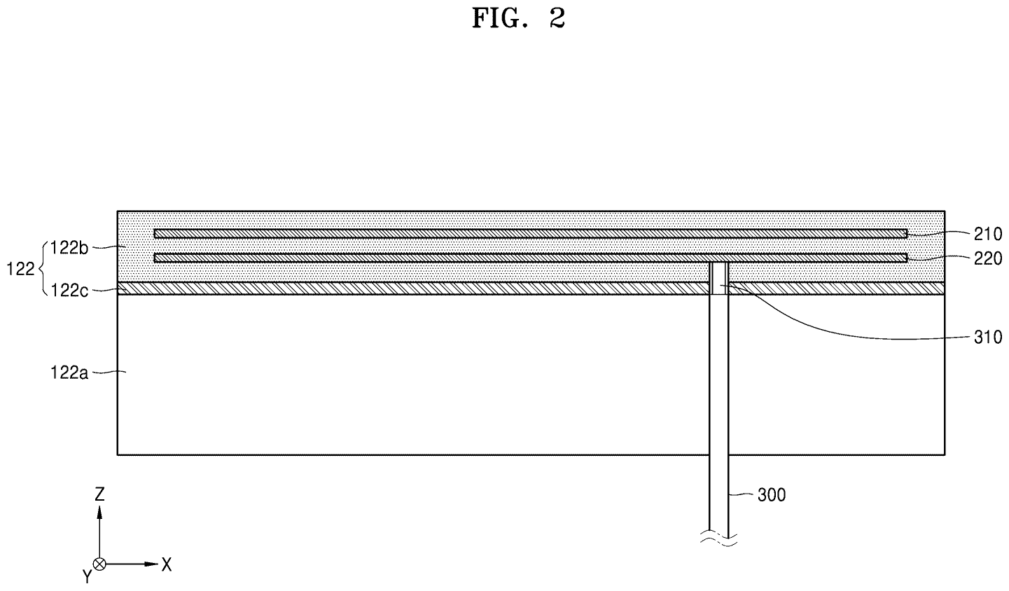

An electrode may be arranged in the chucking unit 122, and the chucking unit 122 may support the substrate W seated thereon by using an electrostatic force generated by a current flowing through the electrode. The chucking unit 122 may include a pedestal 122a, a ceramic puck 122b, and an adhesive layer 122c. A structure of the chucking unit 122 and the electrode arranged therein are described below with reference to FIGS. 2 to 6B.

The chucking unit 122 may be installed to be movable in the vertical direction (e.g., the Z direction) inside the housing 110 by using a driving unit. When the chucking unit 122 is formed to be movable in the vertical direction (e.g., the Z direction), the substrate W may be located in a region exhibiting a more uniform plasma distribution.

A ring assembly 123 may be provided to surround an edge of the chucking unit 122. The ring assembly 123 may have an annular shape and may be configured to support an edge region of the substrate W. The ring assembly 123 may include a focus ring 123a and an insulating ring 123b.

The focus ring 123a may be formed inside the insulating ring 123b and may be provided to surround the chucking unit 122. The focus ring 123a may be formed of, for example, a silicon material and may concentrate plasma on the substrate W.

The insulating ring 123b may be formed an outer side of the focus ring 123a and may be provided to surround the focus ring 123a. For example, the insulating ring 123b may be formed of a quartz material.

In addition, the ring assembly 123 may further include an edge ring formed in contact with an edge of the focus ring 123a. The edge ring may protect a side surface of the chucking unit 122 to prevent the side surface of the chucking unit 122 from being damaged by plasma.

The first gas supply unit 150 may supply a first gas to remove foreign substances remaining on an upper portion of the ring assembly 123 or on an edge portion of the chucking unit 122. The first gas supply unit 150 may include a first gas supply source 151 and a first gas supply line 152.

The first gas supply source 151 may supply a nitrogen gas (e.g., N₂ gas) as the first gas. However, the present inventive concept is not limited thereto, and the first gas supply source 151 may supply another gas, a cleaning agent, or the like.

The first gas supply line 152 may transmit the first gas supplied from the first gas supply source 151 to the edge portion of the chucking unit 122 and the upper portion of the ring assembly 123. For example, the first gas supply line 152 may be arranged to be connected between the chucking unit 122 and the focus ring 123a. The first gas supply line 152 may be provided inside the focus ring 123a and may be formed to be connected between the chucking unit 122 and the focus ring 123a.

A heating unit 124 and the cooling unit 125 may control a temperature so that the substrate W may maintain a process temperature when an etching process is performed inside the housing 110. The heating unit 124 may be provided as a heating wire, and the cooling unit 125 may be provided as a cooling line through which a refrigerant flows.

The heating unit 124 and the cooling unit 125 may be installed inside the substrate support unit 120 to allow the substrate W to maintain the process temperature. According to an embodiment of the present inventive concept, the heating unit 124 may be arranged inside the chucking unit 122, and the cooling unit 125 may be installed inside the base plate 121.

Furthermore, the cooling unit 125 may be supplied with the refrigerant by using a cooling apparatus 126. The cooling apparatus 126 may be installed outside the housing 110.

The plasma generation unit 130 may generate plasma from a gas remaining in a discharge space. Here, the discharge space may refer to a space located above the substrate support unit 120, in the inner space of the housing 110.

The plasma generation unit 130 may generate plasma in the discharge space that is inside the housing 110 by using an inductively coupled plasma (ICP) source. Here, the plasma generation unit 130 may use an antenna unit 193 that is installed in the upper module 190 as an upper electrode, and the plasma generation unit 130 may use the substrate support unit 120 as a lower electrode.

However, the present inventive concept is not limited thereto. The plasma generation unit 130 may generate plasma in the discharge space that is inside the housing 110 by using a capacitively coupled plasma (CCP) source. Here, the plasma generation unit 130 may use the shower head unit 140 as an upper electrode and use the substrate support unit 120 as a lower electrode. In addition, the plasma generation unit 130 may generate a microwave plasma source, a remote plasma source, and the like.

The plasma generation unit 130 may include an upper electrode, a lower electrode, an upper power source 131, a first lower power source 133, and a second lower power source 135.

The upper power source 131 may apply power to the upper electrode, i.e., the antenna unit 193. The upper power source 131 may be provided to control characteristics of plasma. The upper power source 131 may be, for example, provided to control ion bombardment energy.

Although one upper power source 131 is shown in FIG. 1, a plurality of upper power sources 131 may be provided in the present embodiment. When the plurality of upper power sources 131 are provided, the substrate processing apparatus 100 may further include a first matching network electrically connected to the plurality of upper power sources 131.

The first matching network may match frequency powers of different sizes input from the respective upper power sources 131 and apply the matched frequency powers to the antenna unit 193. In addition, a first impedance matching circuit may be provided for impedance matching on an upper transmission line 132 connecting the upper power source 131 to the antenna unit 193. The first impedance matching circuit may act as a lossless passive circuit so that electrical energy may be effectively (e.g., maximally) transmitted from the upper power source 131 to the antenna unit 193.

The first lower power source 133 and the second lower power source 135 may apply power to the lower electrode, i.e., the substrate support unit 120. For example, the first lower power source 133 may apply plasma source radio frequency (RF) power that generates plasma, and the second lower power source 135 may apply bias RF power that serves to pull the generated plasma. The first lower power source 133 and the second lower power source 135 may control plasma characteristics together with the upper power source 131.

Although the first lower power source 133 and the second lower power source 135 are each shown as one in FIG. 1, a plurality of first lower power sources 133 and a plurality of second lower power sources 135 may be provided in the present embodiment. When a plurality of first lower power sources 133 and a plurality of second lower power sources 135 are provided, a second matching network electrically connected to a plurality of lower power sources may be included.

The second matching network may match pieces of frequency power of different sizes that is input from the respective lower power sources and apply the matched pieces of frequency power to the substrate support unit 120. In addition, a second impedance matching circuit may be provided for impedance matching on a first lower transmission line 134 and a second lower transmission line 136 which respectively connect the first lower power source 133 and the second lower power source 135 to the substrate support unit 120. Like the first impedance matching circuit, the second impedance matching circuit may act as a lossless passive circuit so that electrical energy may be effectively (e.g., maximally) transmitted from the first lower power source 133 or the second lower power source 135 to the substrate support unit 120.

The shower head unit 140 may be installed to vertically face the substrate support unit 120 inside the housing 110. The shower head unit 140 may be provided with a plurality of gas feeding holes 141 to inject a gas into the housing 110 and may be provided to have a greater diameter than that of the substrate support unit 120. Furthermore, the shower head unit 140 may be made of, for example, a silicon component, but the shower head unit 140 is not limited thereto, and may also be made of, for example, a metal component.

The second gas supply unit 160 may supply a process gas (a second gas) into the housing 110 through the shower head unit 140. The second gas supply unit 160 may include a second gas supply source 161 and a second gas supply line 162.

The second gas supply source 161 may supply, as the process gas, an etching gas used to process the substrate W. The second gas supply source 161 may supply, as the etching gas, a gas (e.g., a gas such as SF₆ or SF₄) including a fluorine component. The one second gas supply source 161 may be provided to supply the etching gas to the shower head unit 140. However, the present embodiment is not limited thereto, and a plurality of second gas supply sources 161 may be provided to supply the process gas to the shower head unit 140.

The second gas supply line 162 may connect the second gas supply source 161 to the shower head unit 140. The second gas supply line 162 may transfer the process gas, which is supplied from the second gas supply source 161, to the shower head unit 140 so that the etching gas may flow into the housing 110.

In addition, when the shower head unit 140 is divided into a center zone, a middle zone, and an edge zone, the second gas supply unit 160 may further include a gas distributor and a gas distribution line to supply the process gas to each zone of the shower head unit 140.

In addition, the second gas supply unit 160 may further include a third gas supply source for supplying a deposition gas. The third gas supply source may supply the deposition gas to the shower head unit 140 to enable anisotropic etching by protecting a side surface of a pattern of the substrate W. The third gas supply source may supply a gas such as C₄F₈, C₂F₄, or the like as the deposition gas.

The wall liner unit 170 may protect an inner side surface of the housing 110 from arc discharge that is generated when the process gas is excited. The wall liner unit 170 may also protect the inner side surface of the housing 110 from impurities generated during a substrate processing process, and the like. The wall liner unit 170 may have a cylindrical shape in which an upper portion and a lower portion are each opened inside the housing 110. For example, the wall liner unit 170 may have an annular shape.

The wall liner unit 170 may be provided adjacent to an inner wall of the housing 110. The wall liner unit 170 may include a support ring 171 protruding outwardly from an upper portion of the wall liner unit 170 to support the wall liner unit 170. For example, the support ring 171 may extend into a groove that is formed into a sidewall (or, e.g., an inner wall) of the housing 110.

The baffle unit 180 may exhaust plasma process by-products, an unreacted gas, or the like. The baffle unit 180 may be arranged between the inner wall of the housing 110 and the substrate support unit 120. The baffle unit 180 may have an annular shape and may include a plurality of through holes passing therethrough in the vertical direction. The baffle unit 180 may control flow of the process gas according to the number and shape of through holes.

The upper module 190 may be installed to cover an open upper portion of the housing 110. The upper module 190 may include a window portion 191, an antenna portion 192, and the antenna unit 193.

The window portion 191 may cover the upper portion of the housing 110 to seal the inner space of the housing 110. The window portion 191 may be provided in a shape of a plate (e.g., a disk or a cylinder) and may include an insulating material (e.g., aluminum oxide (Al₂O₃)). A through hole, through which the second gas supply line 162 is inserted, may be formed in the window portion 191, and a coating film may be formed on a surface of the window portion 191 to suppress a generation of particles when the plasma process is performed inside the housing 110.

The antenna portion 192 may be installed on the window portion 191 and a space having a certain size may be provided in the antenna portion 192 so that the antenna unit 193 may be arranged therein. The antenna portion 192 may be formed in a cylindrical shape having an open lower portion and may be provided to have a diameter corresponding to that of the housing 110. The antenna portion 192 may be provided to be detachable from the window portion 191.

The antenna unit 193 may function as an upper electrode and may be mounted with a coil provided to form a closed loop. The antenna unit 193 may generate a magnetic field and an electric field inside the housing 110 on the basis of power supplied from the upper power source 131, and may excite, into plasma, the gas flowing into the housing 110 through the shower head unit 140. The antenna unit 193 may be mounted with a coil in the form of a planar spiral. However, the present embodiment is not limited thereto, and a structure, a size, and the like of the coil may be variously modified by one of ordinary skill in the art.

FIG. 2 is an enlarged cross-sectional view illustrating a chucking unit according to an embodiment of the present inventive concept.

Referring to FIGS. 1 and 2, the chucking unit 122 may include a pedestal 122a, a ceramic puck 122b, and an adhesive layer 122c.

The pedestal 122a may be arranged on the base plate 121. The pedestal 122a may have a structure that is arranged underneath the ceramic puck 122b to support the ceramic puck 122b. A source RF for generating plasma may be applied to the pedestal 122a. For example, the pedestal 122a may be supplied with the plasma source RF for generating plasma from the first lower power source 133. In addition, according to embodiments of the present inventive concept, the heating unit 124 may be arranged inside the pedestal 122a.

The ceramic puck 122b may be arranged on the pedestal 122a. The ceramic puck 122b may be attached onto the pedestal 122a through the adhesive layer 122c disposed therebetween.

The ceramic puck 122b may be configured to support the substrate W. For example, the substrate W may be disposed on and supported by an upper surface of the ceramic puck 122b. The ceramic puck 122b may have a smaller thickness than that of the pedestal 122a. For example, the ceramic puck 122b may include a ceramic disk having a thickness of about 1 mm to about 2 mm.

A chucking electrode 210 and a bias electrode 220 may be arranged inside the ceramic puck 122b. The chucking electrode 210 and the bias electrode 220 may be buried within the ceramic puck 122b, and a voltage may be applied to each of the chucking electrode 210 and the bias electrode 220. Each of the chucking electrode 210 and the bias electrode 220 may be formed of disk-shaped metal. For example, the chucking electrode 210 and the bias electrode 220 may be formed of one of platinum (Pt), tungsten (W), and/or a molybdenum alloy (Mo-alloy).

The chucking electrode 210 may be spaced apart from the bias electrode 220 in the vertical direction (e.g., the Z direction) inside the ceramic puck 122b and may be arranged above the bias electrode 220. A voltage may be applied to the chucking electrode 210 to provide a chucking force for fixing the substrate W onto the ceramic puck 122b.

The bias electrode 220 may be spaced apart from the chucking electrode 210 in the vertical direction (e.g., the Z direction) inside the ceramic puck 122b and may be arranged under the chucking electrode 210. A bias RF voltage capable of controlling energy and flow of plasma ions may be applied to the bias electrode 220.

According to embodiments of the present inventive concept, a high-pressure non-sinusoidal generator (NSG) voltage may be applied to the bias electrode 220. Compared to the case of using an existing sine wave-type voltage, when the NSG voltage is used, only ions having high energy may be selectively generated. For example, the high-pressure NSG voltage may be used to control energy, flux, and the like of ions and obtain higher ion energy, according to variables such as the size of the NSG voltage and the time of change in NSG voltage. For example, the NSG voltage of 400 kHz may be applied to the bias electrode 220.

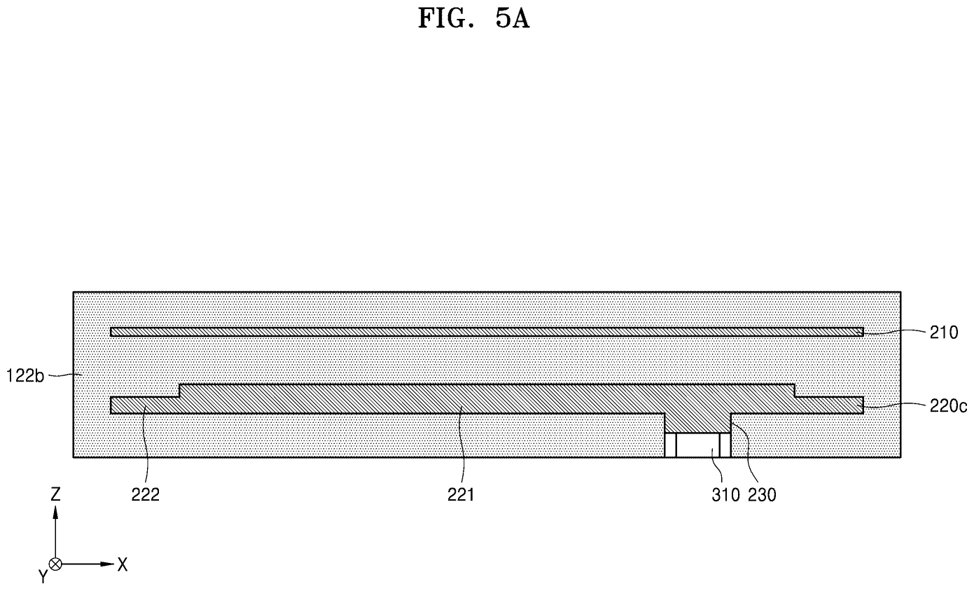

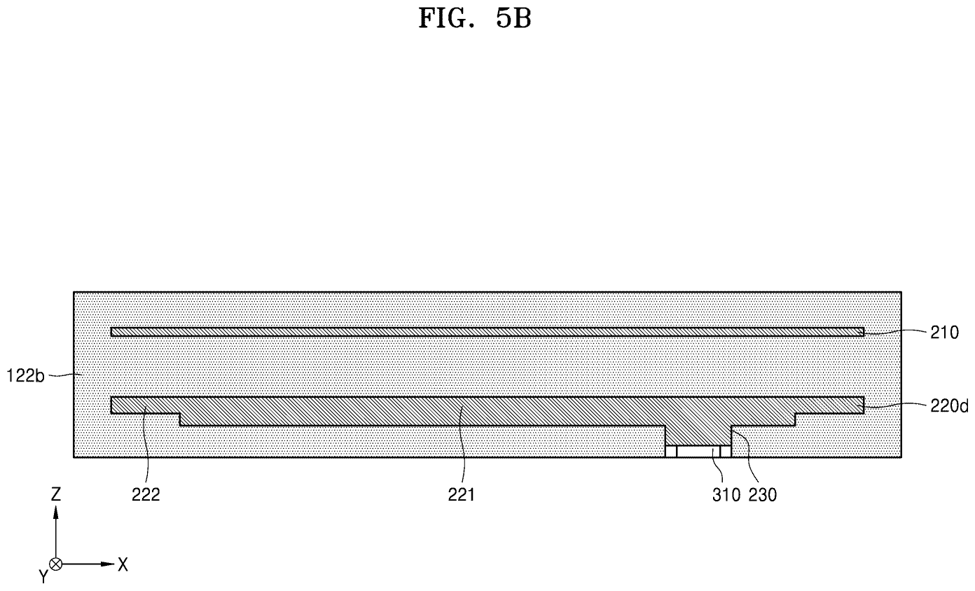

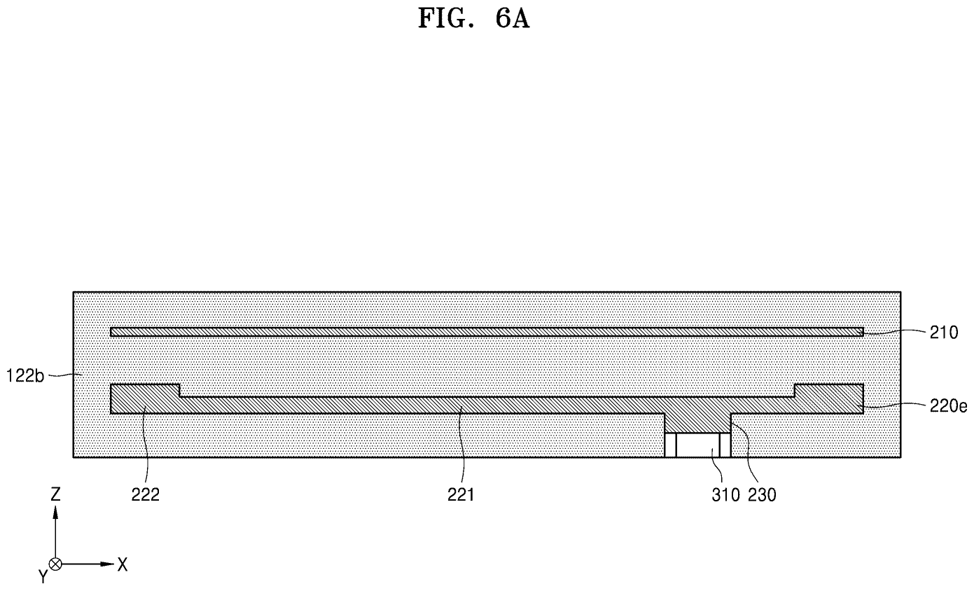

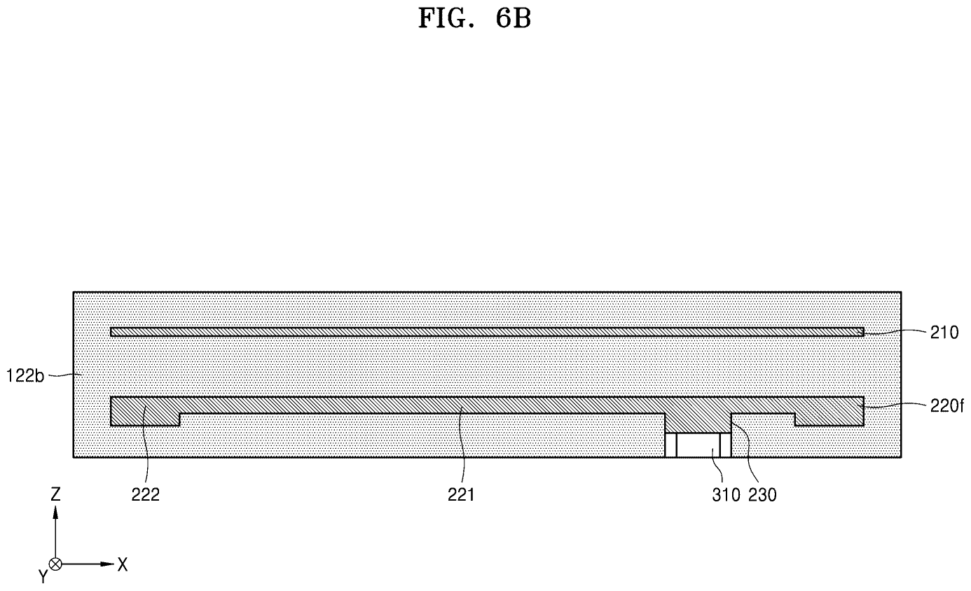

The bias electrode 220 is illustrated in FIG. 2 as having a disk shape with a uniform thickness, but is not limited thereto and may be formed to have a non-uniform thickness. For example, the bias electrode 220 may have a disk shape in which a thickness of a center portion 221 (refer to FIG. 5A) is different from a thickness of an edge portion 222 (refer to FIG. 5A), and the description thereof is given below with reference to FIGS. 5A to 6B.

A bias rod 300 may be arranged underneath the bias electrode 220. The bias rod 300 may pass through the pedestal 122a and the adhesive layer 122c to extend in the vertical direction (e.g., the Z direction). The bias rod 300 may transmit the bias RF voltage to the bias electrode 220. For example, the bias rod 300 may transmit the bias RF voltage, which is provided from the second lower power source 135, to the bias electrode 220.

The bias rod 300 may be connected to the bias electrode 220 through a terminal portion 310. The terminal portion 310 may be configured to maintain contact with a lower surface of the bias electrode 220 without giving a significant impact to the bias electrode 220.

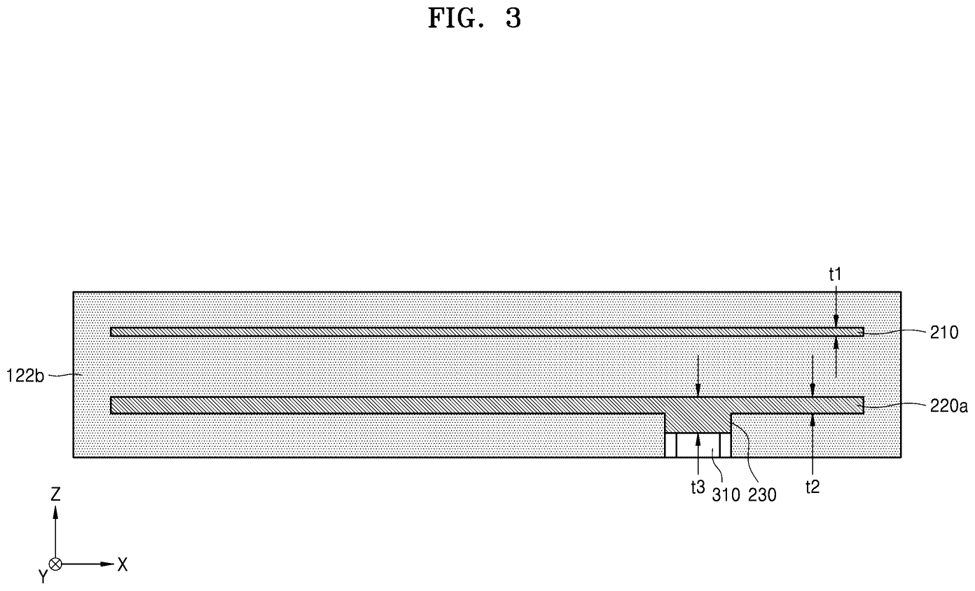

The shape of the bias electrode 220 and a connection structure of the bias electrode 220 with the terminal portion 310 are described below with reference to FIGS. 3 to 7.

FIG. 3 is a cross-sectional view of a ceramic puck according to an embodiment of the present inventive concept.

Referring to FIG. 3, a chucking electrode 210 and a bias electrode 220a may be arranged to be spaced apart from each other inside a ceramic puck 122b.

A thickness t2 of the bias electrode 220a may be greater than a thickness t1 of the chucking electrode 210. A relatively greater voltage may be applied to the bias electrode 220 compared to the chucking electrode 210. Heat may be generated when a high current flows in the bias electrode 220a, and an appropriate thickness for the bias electrode 220a may prevent damage to the bias electrode 220a due to the generated heat. For example, the thickness t1 of the chucking electrode 210 may be about 5 μm to about 10 μm, and the thickness t2 of the bias electrode 220 may be about 50 μm to about 200 μm.

The bias electrode 220a may include a reinforcement portion 230 having a locally reinforced thickness. A terminal portion 310 of a bias rod 300 may be connected to the reinforcement portion 230.

A diameter of the terminal portion 310 may be less than a diameter of the bias electrode 220a, and thus, when a high-pressure NSG voltage is applied to the bias electrode 220a through the terminal portion 310, a high current may flow per unit area in a connection portion between the terminal portion 310 and the bias electrode 220a. The bias electrode 220a may include the reinforcement portion 230 having the locally reinforced thickness to reduce a density of the current flowing through the connection portion between the terminal portion 310 and the bias electrode 220a. For example, when the thickness t2 of the bias electrode 220 is about 50 μm to about 200 μm, a thickness t3 of the reinforcement portion 230 may be about 200 μm to about 1,000 μm.

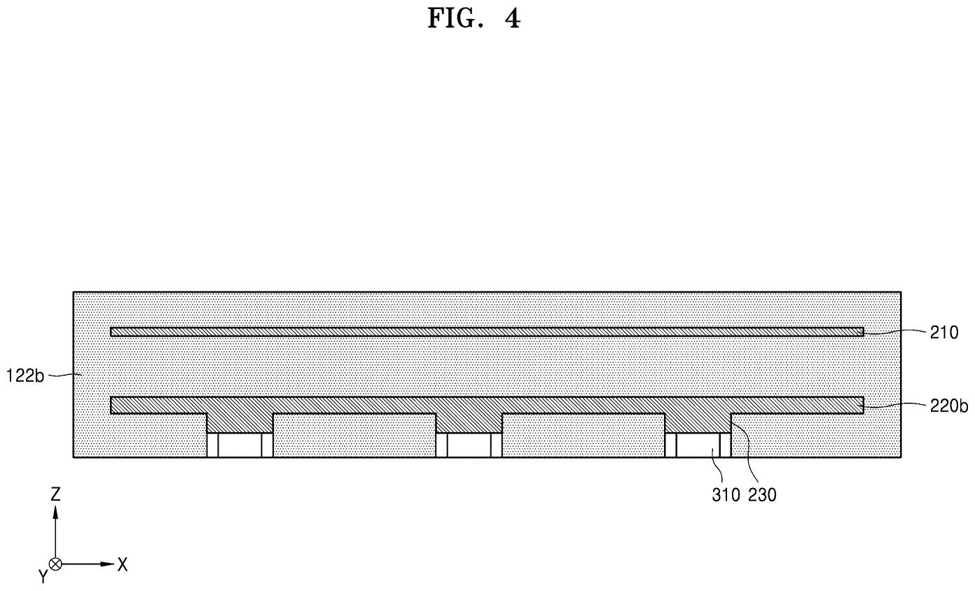

FIG. 4 is a cross-sectional view of a ceramic puck according to an embodiment of the present inventive concept. To the extent that the description of various elements is omitted, it may be assumed that these elements are at least similar to corresponding elements that have already been described.

Referring to FIG. 4, a chucking electrode 210 and a bias electrode 220b may be arranged to be spaced apart from each other inside a ceramic puck 122b, and the bias electrode 220b may include a plurality of reinforcement portions 230. The plurality of reinforcement portions 230 may be arranged to be spaced apart from one another in a horizontal direction (e.g., an X direction and/or a Y direction) on a lower surface of the bias electrode 220b. A terminal portion 310 may be connected to each of the reinforcement portions 230 to distribute and transmit a current to the bias electrode 220b.

FIGS. 5A and 5B are cross-sectional views of a ceramic puck including a bias electrode having a thick center portion, according to an embodiment of the present inventive concept, and FIGS. 6A and 6B are cross-sectional views of a ceramic puck including a bias electrode having a thick edge portion, according to an embodiment of the present inventive concept. To the extent that the description of various elements are omitted, it may be assumed that these elements are at least similar to corresponding elements that have already been described.

Compared to the bias electrode 220a of FIG. 3, bias electrodes 220c, 220d, 220e, and 220f of FIGS. 5A, 5B, 6A, and 6B may each have a disk shape that has a nonuniform thickness. The bias electrodes 220c, 220d, 220e, and 220f according to embodiments of the present inventive concept may have disk shapes in which a thickness of center portions 221 including centers of the disk shapes is different from a thickness of edge portions 222 including outer circumferences. The bias electrodes 220c, 220d, 220e, and 220f may be formed such that the thickness of the center portions 221 is different from the thickness of the edge portions 222, to control plasma for processing the substrate W.

The bias electrodes 220c and 220d according to embodiments of the present inventive concept may be formed such that the thickness of the center portions 221 is greater than the thickness of the edge portions 222.

Referring to FIG. 5A, the bias electrode 220c according to an embodiment of the present inventive concept may be formed such that a lower surface of the center portion 221 and a lower surface of the edge portion 222 are at the same vertical level, and an upper surface of the center portion 221 protrudes upwards beyond an upper surface of the edge portion 222.

The bias electrode 220c may include a reinforcement portion 230 to be connected to a terminal portion 310. The reinforcement portion 230 may be formed to protrude downwards beyond the lower surface of the bias electrode 220c. Although FIG. 5A illustrates that the reinforcement portion 230 is arranged on the lower surface of the center portion 221, the reinforcement portion 230 is not limited thereto and may be formed at an any location to which the terminal portion 310 may be connected. According to embodiments of the present inventive concept, when the terminal portion 310 is connected to the center portion 221 of the bias electrode 220c and a current having a sufficiently high density is transmitted to a connection portion between the terminal portion 310 and the center portion 211, the reinforcement portion 230 may be omitted.

Referring to FIG. 5B, the bias electrode 220d according to an embodiment of the present inventive concept may be formed such that the upper surface of the center portion 221 and the upper surface of the edge portion 222 are at the same vertical level, and the lower surface of the center portion 221 protrudes downwards beyond the lower surface of the edge portion 222. The bias electrode 220d may include the reinforcement portion 230 to be connected the terminal portion 310. Although FIG. 5B illustrates that the reinforcement portion 230 is arranged on the lower surface of the center portion 221, the reinforcement portion 230 is not limited thereto and may be omitted.

The bias electrodes 220e and 220f according to embodiments of the present inventive concept may be formed such that the thickness of the edge portions 222 is greater than the thickness of the center portion 221.

Referring to FIG. 6A, the bias electrode 220e according to an embodiment of the present inventive concept may be formed such that the lower surface of the center portion 221 and the lower surface of the edge portion 222 are at the same vertical level, and the upper surface of the edge portion 222 protrudes upwards beyond the upper surface of the center portion 221.

The bias electrode 220e may include the reinforcement portion 230 to be connected to the terminal portion 310. The reinforcement portion 230 may be formed to protrude downwards from the lower surface of the bias electrode 220e. Although FIG. 6A illustrates that the reinforcement portion 230 is arranged on the lower surface of the center portion 221, the reinforcement portion 230 is not limited thereto and may be formed at an any location to which the terminal portion 310 may be connected.

Referring to FIG. 6B, the bias electrode 220f according to an embodiment of the present inventive concept may be formed such that the lower surface of the center portion 221 and the upper surface of the edge portion 222 are at the same vertical level, and the lower surface of the edge portion 222 protrudes downwards beyond the lower surface of the center portion 221. The bias electrode 220f may include the reinforcement portion 230 to be connected to the terminal portion 310.

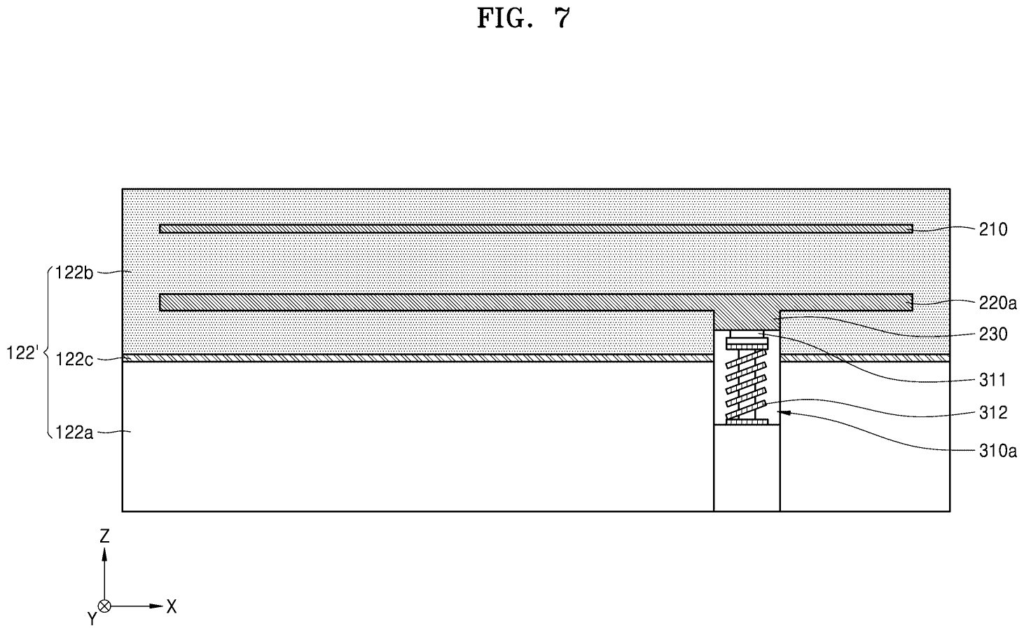

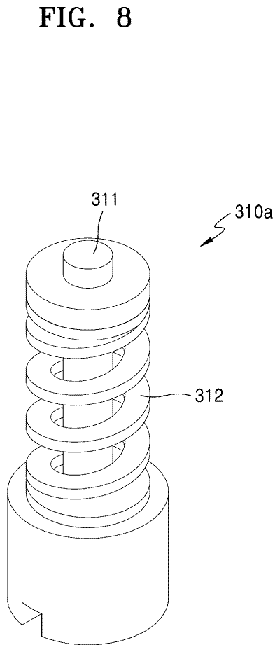

FIG. 7 is an enlarged cross-sectional view illustrating a chucking unit according to an embodiment of the present inventive concept, and FIG. 8 is a perspective view schematically illustrating a structure of a terminal portion of FIG. 7.

A chucking unit 122′ shown in FIG. 7 may include a terminal portion 310a that may reduce an impact applied to a bias electrode 220a. Referring to FIGS. 7 and 8, a terminal portion 310a according to an embodiment of the present inventive concept may have a structure capable of reducing an impact that may be applied to a bias electrode 220a having a small thickness while maintaining contact with the bias electrode 220a. The terminal portion 310a according to an embodiment of the present inventive concept may include a contact portion 311 and a spring 312.

The contact portion 311 may be arranged to be in contact with a lower surface of the bias electrode 220a. The contact portion 311 may be formed of metal having conductivity and may transmit a voltage to the bias electrode 220a. For example, the contact portion 311 may be formed of silver (Ag) or tungsten (W) having a small resistance.

The spring 312 may absorb the impact that may be applied by the terminal portion 310a to the bias electrode 220a and may simultaneously maintain the contact between the contact portion 311 and the reinforcement portion 230. The spring 312 may include an insulating material such that spring 312 does not interfere with transmission of a current by the terminal portion 310a. For example, the spring 312 may include polyetherether ketone (PEEK) or ceramic.

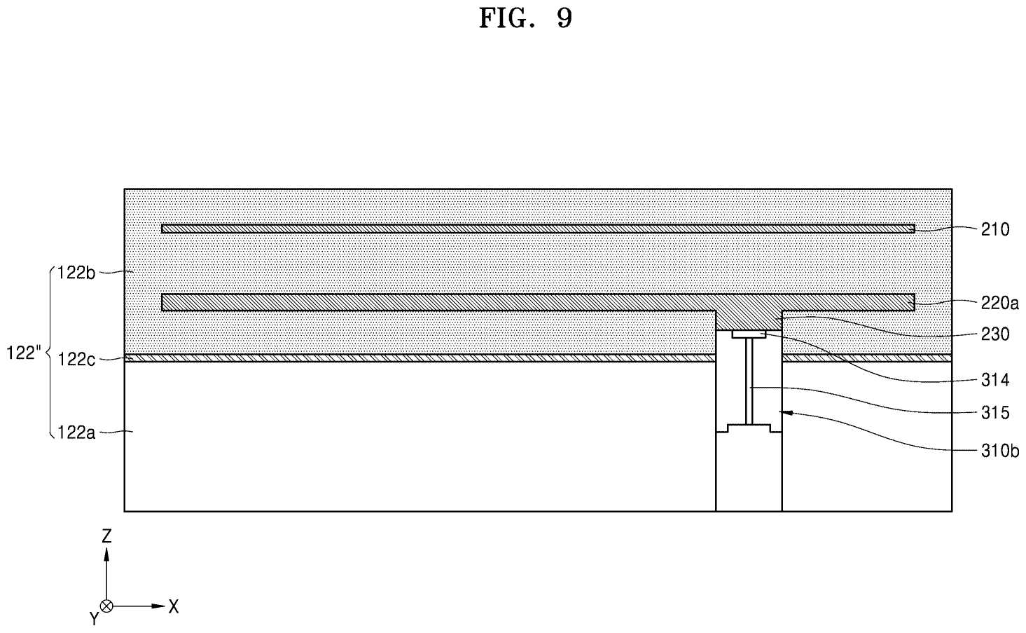

FIG. 9 is an enlarged cross-sectional view illustrating a chucking unit according to an embodiment of the present inventive concept. A chucking unit 122″ shown in FIG. 9 may include a terminal portion 310b that may reduce an impact that may be applied to a bias electrode 220a having a small thickness while maintaining contact with the bias electrode 220a, and may have a different structure from that of the terminal portion 310a of FIG. 8.

Referring to FIG. 9, the terminal portion 310b according to an embodiment of the present inventive concept may include a connection tip 314 and a wire 315. The connection tip 314 and the wire 315 may be components capable of each applying a high current and may have structures that are sintered together.

The connection tip 314 may be attached to a lower surface of the bias electrode 220a. The connection tip 314 may include metal having conductivity and may transmit a voltage to the bias electrode 220a. For example, the connection tip 314 may include brass or silver.

The wire 315 may absorb the impact that may be applied by the terminal portion 310b to the bias electrode 220a. The wire 315 may include a metal material capable of applying a high current. For example, the wire 315 may be connected to the connection tip 314 by soldering.

In the substrate processing apparatus 10 according to an embodiment of the present inventive concept, the bias electrode 220 may be arranged inside the ceramic puck 122b rather than inside the pedestal 122a, and thus, a source RF and a bias RF may be separated and transmitted to the chucking unit 122. In particular, according to an embodiment of the present inventive concept, the substrate processing apparatus 10, which may selectively generate only ions having high energy by applying a high-pressure NSG voltage to the bias electrode 220, may be provided.

In addition, the substrate processing apparatus 10 according to an embodiment of the present inventive concept may transmit a high voltage to the substrate W that is arranged on the upper surface of the ceramic puck 122b and may prevent arcing of the chucking unit 122 that includes the pedestal 122a, by arranging, inside the ceramic puck 122b, the bias electrode 220 to which the high-pressure NSG voltage is applied.

While the present inventive concept has been described with reference to embodiments thereof, it will be understood by those of ordinary skill in the art that various changes in form and details may be made thereto without departing from the spirit and scope of the present inventive concept.

What is claimed is:

1. A substrate processing apparatus comprising:
a ceramic puck supporting a substrate; and
a pedestal arranged underneath the ceramic puck and to which a source radio frequency (RF) for generating plasma is applied, wherein a bias electrode, to which a non-sinusoidal generator voltage is applied, is arranged inside the ceramic puck.

2. The substrate processing apparatus of claim 1, wherein the bias electrode has a disk shape and comprises a reinforcement portion having a locally reinforced thickness, and a terminal portion of a bias rod is connected to a lower surface of the bias electrode through the reinforcement portion.

3. The substrate processing apparatus of claim 2, wherein the bias electrode comprises a plurality of reinforcement portions, and the terminal portion is connected to each of the plurality of reinforcement portions.

4. The substrate processing apparatus of claim 2, wherein the terminal portion is configured to maintain contact with the lower surface of the bias electrode.

5. The substrate processing apparatus of claim 4, wherein the terminal portion comprises a contact portion and a spring, wherein the contact portion is in contact with the bias electrode, and the spring supports the contact portion toward the lower surface of the bias electrode.

6. The substrate processing apparatus of claim 4, wherein the terminal portion includes a connection tip and a wire, wherein the connection tip is attached to the bias electrode, and the wire connects the connection tip to the bias rod and applies a high current.

7. The substrate processing apparatus of claim 2, wherein the bias electrode has a disk shape having a thickness of about 50 μm to about 200 μm and comprises the reinforcement portion having a thickness of about 200 μm to about 1000 μm.

8. The substrate processing apparatus of claim 1, wherein the ceramic puck comprises a chucking electrode configured to apply a chucking force to the substrate, and the chucking electrode is arranged above the bias electrode to be spaced apart from the bias electrode inside the ceramic puck.

9. The substrate processing apparatus of claim 8, wherein the chucking electrode has a disk shape having a thickness of about 5 μm to about 10 μm.

10. A substrate processing apparatus comprising:
a housing;
a shower head unit installed inside the housing and supplying a process gas for processing a substrate in the housing;
a substrate support unit installed under the shower head unit inside the housing, wherein the substrate is disposed on the substrate support unit; and
a plasma generation unit configured to generate plasma by using the process gas to process the substrate, wherein the substrate support unit comprises:
a chucking unit supporting the substrate by using an electrostatic force; and
a base plate supporting the chucking unit, wherein the chucking unit comprises:
a ceramic puck supporting the substrate and having arranged therein a bias electrode, to which a non-sinusoidal voltage is applied; and
a pedestal arranged underneath the ceramic puck and to which a source RF for generating plasma is applied, wherein the bias electrode has a disk shape and comprises a reinforcement portion having a locally reinforced thickness, and a terminal portion of a bias rod is connected to a lower surface of the bias electrode through the reinforcement portion.

11. A substrate processing apparatus comprising:
a ceramic puck supporting a substrate; and
a pedestal arranged underneath the ceramic puck and to which a source radio frequency (RF) for generating plasma is applied, wherein a bias electrode having a disk shape, in which a thickness of a center portion is different from a thickness of an edge portion, is arranged inside the ceramic puck.

12. The substrate processing apparatus of claim 11, wherein the thickness of the center portion of the bias electrode is greater than the thickness of the edge portion of the bias electrode.

13. The substrate processing apparatus of claim 12, wherein a lower surface of the center portion and a lower surface of the edge portion are at a same vertical level, and an upper surface of the center portion protrudes upwards beyond an upper surface of the edge portion.

14. The substrate processing apparatus of claim 12, wherein an upper surface of the center portion and an upper surface of the edge portion are at a same vertical level, and a lower surface of the center portion protrudes downwards beyond a lower surface of the edge portion.

15. The substrate processing apparatus of claim 11, wherein the thickness of the edge portion of the bias electrode is greater than the thickness of the center portion of the bias electrode.

16. The substrate processing apparatus of claim 15, wherein a lower surface of the center portion and a lower surface of the edge portion are at a same vertical level, and an upper surface of the edge portion protrudes upwards beyond an upper surface of the center portion.

17. The substrate processing apparatus of claim 15, wherein an upper surface of the center portion and an upper surface of the edge portion are at a same vertical level, and a lower surface of the edge portion protrudes downwards beyond a lower surface of the center portion.

18. The substrate processing apparatus of claim 11, wherein the bias electrode comprises a reinforcement portion having a locally reinforced thickness, and wherein a terminal portion of a bias rod is connected to a lower surface of the bias electrode through the reinforcement portion.

19. The substrate processing apparatus of claim 18, wherein the bias electrode comprises a plurality of reinforcement portions at the center portion, and the terminal portion is connected to each of the plurality of reinforcement portions.

20. The substrate processing apparatus of claim 18, wherein the terminal portion comprises a spring or wire structure disposed on the lower surface of the bias electrode.
